(19) United States
(12) Patent Application Publication
(10) Pub. No.: US 2025/0230538 A1
(43) Pub. Date: Jul. 17, 2025

(54) METHOD FOR FORMING HARD AND ULTRA-SMOOTH A-C BY SPUTTERING

(71) Applicant: Oerlikon Surface Solutions AG, Pfäffikon, Pfäffikon (CH)

(72) Inventors: JULIEN KERAUDY, BUCHS (CH); SEBASTIEN GUIMOND, ST. GALLEN (CH); SIEGFRIED KRASSNITZER, FELDKIRCH (AT)

(21) Appl. No.: 18/703,218

(22) PCT Filed: Oct. 4, 2022
(86) PCT No.: PCT/EP2022/000088

§ 371 Date: Apr. 19, 2024

(30) Foreign Application Priority Data
Oct. 22, 2021 (DE) 10 2021 005 266.8

(51) Int. Cl. C23C 14/35; C23C 14/02; C23C 14/06; C23C 14/34

(52) U.S. Cl. CPC C23C 14/35; C23C 14/022; C23C 14/0605; C23C 14/3485

(57) ABSTRACT

A method for forming a coating on a substrate with the help of a coating device and a device for providing non-reactive ions. A negative bias is applied to the substrate for effecting an ion bombardment on the material deposited on the substrate thereby increasing the density of the material deposited.

The present invention relates to a wear resistant hard carbon coating and a method to enhance its mechanical properties without sacrificing the high surface quality, in comparison to the state of the art. More specifically, the invention relates to a method operating a pulsed plasma carbon sputter source with an adjacent auxiliary plasma source during the a-C film growth, offering a periodic but intense ion bombardment treatment leading to coating mechanical properties close to those pertaining to high sp3 fraction ta-C films even at low temperature.

Hard carbon coatings such as hydrogenated doped (a-C: H) or hydrogen-free amorphous diamond-like carbon (DLC), the latter often referred to as a-C or as ta-C depending of the sp3 bond fraction, are considered today as one of the most effective protective solutions for attaining improved wear resistance on surfaces of substrate tools during demanding cutting and forming operations or precision components (i.e. engine parts for the automotive sector or mechanical engineering components) operated under extreme loading conditions or subjected to extreme friction and contact pressures with other sliding partners.

High-quality hard carbon coatings are well-known to exhibit an exceptional combination of properties such as high hardness, high wear resistance in dry running and poor lubrication conditions, low friction coefficient and chemical inertness, that can be tailored specifically (e.g. by modulating sp3/sp2 hybridization ratio, by tuning the hydrogen content or by the selection of additional metallic and non-metallic doping elements) to meet the performance requirements of different operating conditions. Further details regarding the features and industrial applications of DLC coatings can be found in writing, among others by J. Vetter in “Surface & Coatings Technology 257 (2014) 213-240” and A. Grill in “Diamond and Related Materials 8 (1999) 428-434”.

Hydrogen-free amorphous carbon coatings such as a-C and ta-C are known to provide higher hardness and hence higher abrasive wear resistance compared to a-C: H coatings while keeping a very low coefficient of friction. With a sp3 fraction as high as 85%, ta-C coatings are classified as superhard coating with a nanoindentation hardness around 40-60 GPa which makes them an excellent solution for components that are exposed to ex-treme thermal and mechanical conditions over the long-term, including shafts and seals or piston pins that must work in severe tribological environments.

High-quality ta-C carbon coatings are commonly deposited under appropriate thermodynamic and kinetic growth conditions by means of physical vapor deposition (PVD). The formation of high sp3 fraction in a-C is generally attributed to subsurface densification generated by the displacement of C atoms (knock-on atoms) resulting in the transformation of the surrounding carbon-carbon bonds from sp2 to sp3 into subsurface positions. This displacement is due to energy and momentum transfer to atoms close to the ion impact site by ion species bombarding the growing film. It is commonly assumed that this densification process is obtained under suitable kinetic conditions such that ener-getic ions are incident at the substrate with energies≤100 eV, above the carbon atom displacement threshold energy of about 25 eV, and most importantly with high ion to neutral flux ratios (ϕi/ϕn). The latter is a key parameter to achieve the formation of dense and hard ta-C coating and for that requires a highly ionized deposition process.

A well-known in the art method to achieve highly ionized plasma to produce hard, dense and wear-resistant ta-C coatings at a relatively high productivity is the vacuum arc evaporation method. Vacuum arc evaporation method generate a highly ionized carbon plasma which is particularly attractive as it offers control of the kinetic energy of the depositing carbon ion flux by using a substrate bias, for example.

The US20190040518A1 discloses a wear resistant hard carbon layer onto substrates in a vacuum chamber from a graphite cathode by means of a low-voltage pulsed arc. The wear-resistant hard carbon layer has a wear-resistant layer consisting of aa tetrahedral amorphous carbon (ta-C), and a titanium adhesion layer between the substrates and the wear protection layer. The adhesion layer is also applied by low-voltage pulsed arc.

However, a disadvantage of arc evaporation processes is the generation and incorporation into the coatings of a large amount of macro-particles or so-called droplets which result in coating defects and hence undesirable inhomogeneities in the layer, unfavorable high coating roughness and for some applications lower coating performance. In tribological applications this can lead to higher counter body wear.

Possible solutions to improve the surface quality of arc-evaporated ta-C are post-finishing methods such as brushing or polishing. However, these methods require an additional production step which has an adverse effect on the economy of the coating process.

It is known that methods to filter out these droplets have been proposed. For instance, WO2014177641A1 proposes a method of producing smoother wear-resistant layers of hydrogen-free tetrahedral amorphous carbon (ta-C) without the need of any mechanical and/or chemical machine finishing by means of laser-arc method in which an electrical arc discharge is ignited in the vacuum via a pulse-operated laser beam and with which the ionized components of the plasma can be deflected toward a substrate by magnetic filters in a separate section of the coating chamber. However, the design of these systems is complex and correspondingly expensive, making it difficult to operate the coating process economically. Additionally, the removal of droplets with such a system is usually accompanied by a significant reduction of the deposition rate, which further impacts the economy of the coating process.

It is also possible to produce high-density hydrogen-free ta-C coatings by other deposition methods even when the carbon ion fraction is minimal using alternative source of energetic species, such as in ion-assisted sputtering deposition, in which high flux energetic Ar ions bombard simultaneously thermal C atoms during the film growth.

For example J. Schwan et al, “Tetrahedral amorphous carbon films prepared by magnetron sputtering and dc ion plating”, in Journal Applied physics 79 (1996) 1416, were able to produce ta-C coatings with sp3 fraction of approximately 87%, similar level as vacuum arc evaporation, by achieving a very high incident ion/carbon flux ratio ϕi/ϕn of 10, through proper adjustment of the sputtered source unbalanced magnetic field strength, the use of a RF excitation, a low gas pressure (<10-3 mbar) and a small distance between the target and the substrate (˜3 cm). This way, the substrate is close enough to the dense plasma near the target so that the high density Ar ions provide simultaneously a sputtering flux to the graphite target and a high incident ion flux on the growing film to promote knock-on subplantation during film growth resulting in the transformation of the surrounding carbons from sp2 to sp3 into subsurface positions and the growth of high-density ta-C films.

For reference, conventional industrial sputtering deposition methods such as dc or RF sputtering have typically an ion to carbon flux ratio of ϕi/ϕn<1 since the plasma density around the substrate is very low, ultimately leading to formation of low-density (1.8-2.3 g·cm-3) and soft (<20 GPa) a-C coating.

However, it is well-known that due to the line-of-sight nature of the vaporized flux emitted from the target surface, film thickness uniformity on substrates with different curvatures is controlled by adjusting their z position along the axis of a cathode during deposition. Having a shorter distance as used by J. Schwan et al will dramatically reduce the range of sizes and substrates the process will be able to handle. It is therefore recommended to have a method with a higher degree of flexibility and coating uniformity in order to deposit high-quality ta-C coatings on small and large parts, with flat and curved surfaces.

A well-known alternative approach to achieve highly ionized plasma, density and hardness of sputtered layers similar to those achieved with the arc evaporation method without jeopardizing the surface quality is the so-called HiPIMS method (HIP-IMS=high Power impulse magnetron sputtering).

The process on laboratory level is described in Kouznetsov et al, “A novel pulsed magnetron sputter technique utilizing very high target power densities”, Surface and Coatings Technology 122 (1999), 290-293 and the industrialized process is disclosed by Krassnitzer in WO201243091A1.

In HiPIMS, highly ionized flux of the sputtered material is achieved by applying a very high peak power to the racetrack area (in cm-2) of the cathode target, also defined as peak power density (Ppeak in W·cm-2). As a result of the very high peak power densities, a high density plasma is achieved. In order to stay below the power limit for target/magnetron damage, the high HiPIMS power is applied in a repeated pulse fashion, this way, the average power density (PAv) is kept on a conventional magnetron sputtering level to limit the target temperature below the melting point. HiPIMS pulses are applied with a defined pulse length (tpulse), typically in the range of few microseconds (˜μs) to few milliseconds (˜ms), and a repetition frequency typically in the range of few Hertz to few kilo Hertz, resulting in a duty cycle (percentage of the time the pulse is applied) typically in the range between 0.5 up to 30%. As a result of the high pulsed power densities, a high plasma density is achieved resulting in an increased ionized fraction of the sputtered material. If a negative voltage is applied to the workpieces to be coated, these ions are accelerated towards the workpieces and consequently can be used to produce very dense coatings; this has been described by Samuelsson et al, “Influence of ionization degree on film properties when using high power impulse magnetron sputter-ing”, in Journal of Vacuum Science & Technology A 30 (2012), 031507.

Despite the high plasma density generated by the HiPIMS discharge, carbon by HiPIMS is known to exhibit a very low degree of carbon ionization. The reasons for the difficulties of ionizing carbon are partly due to the low self- and gas-sputter yield, high 1st ionization energy potential (11.3 eV) and a low cross-section electron-impact ionization rendering the probability of ionization of the carbon sputtered flux very low.

The WO2012138279A1 disclosed a sputtering process which leads to a higher amount of the sputtered carbon atoms being ionized compared to standard HiPIMS process. The process mainly involves sputtering carbon with HiPIMS using neon (Ne) or a gas mixture comprising at least 60% neon as the sputtering gas to increase the electron temperature in order to increase the electron impact ionization rate coefficient and thus the probability of ionization by electron-impact of the sputtered carbon atoms.

Despite the improved carbon ion flux, the authors reported with this process the growth of hydrogen free a-C with a film density of maximum 2.57 g·cm-3. Although, K. Bobzin et al, “Synthesis of a-C coatings by HPPMS using Ar, Ne and He as process gases”, in Surface & Coating Technology 308 (2016) 80, have recently reported with this neon HiPIMS process the growth of a-C coatings with a coating hardness of ˜ 45 GPa, the material characterization evidence is not universally consistent and there are conflicting reports on the optimal conditions to achieve high density of tetrahedral bonds.

For most part, studies using neon HiPIMS do not find any operating conditions that yield high sp3 fractions and results with a coating hardness of around 20-30 GPa. This is a consequence of the sputtering process itself, in which the incident ion to carbon flux ratio ϕi/ϕn at the growing film in HiPIMS carbon discharge is at best found close to 5-6.

The strategy to increase the ion to carbon flux ratio by transforming the sputtered carbon atoms into carbon ions requires a large increase of the plasma density and electron temperature, which can only results from the application of a very high peak power during each pulse.

EP2587518B1 discloses a method of depositing hydrogen-free ta-C coatings on substrates of metal or ceramic materials by means of HiPIMS sputtering processes. In EP2587518B1, the authors reported that hydrogen-free ta-C coatings with a hardness of 50 GPa can be readily deposited on a metal or ceramic surface. To achieve such properties, the peak power applied during each pulse is in the range up to 2 megawatts.

As emphasized by Vitelaru et al, “A strategy for Alleviating Micro Arcing during HiPIMS Deposition of DLC coatings”, in the journal Materials 13 (2020) 1038, a common issue in carbon sputtering is the occurrence of micro-arcs. The frequency of arcing depends mainly on the target material quality and its surface state during sputtering but also on the peak power used for sputtering. Since the increase of ionization degree can be achieved by increasing the peak power to the target, further increase of hardness can come with the price of an unwanted higher density of defects on the surface. No data has been provided by the EP2587518B1 to disprove this assumption. We can therefore assume that the hard ta-C coatings as described in EP2587518B1 contains an unfavorable high coating roughness and require the use of a post-finishing method to improve the performance in real applications.

Consequently, there exists a need for an alternative HIPIMS sputtering process for depositing hard carbon coatings which are formed from at least one hydrogen-free tetrahedral amorphous carbon (ta-C) with an ultra-smooth surface, which at the same time exhibit a high hardness (around 50 GPa) and a very good sliding friction properties and preferably the simplest and more flexible industrial process with high degree of process reliability and uniformity.

It is therefore the object of the present invention to provide a wear resistant hard carbon coating by means of HiPIMS, which provides an improved mechanical properties and simultaneously very good sliding friction properties without sacrificing the high surface quality, in comparison to the state of the art.

It is a further objective of the present invention to provide an alternative industrial-suitable coating method for producing tools or components coated with the afore-said high performance ultra-smooth ta-C coatings.

During their experiments to increase the mechanical properties and hence promoting the formation of a larger fraction of sp3 bond in the a-C layer by means of HiPIMS, the inventors have noticed from one hand that the particle flux incident at the growing substrate surface generated by the pulsed power plasma comprises neutral (ϕn) and ion (ϕi) species. The neutral flux ϕn consists of carbon atoms with rather low kinetic energies resulting from the energy distribution of the sputter process and amounts to a few eV (about 5 eV). The analysis of the ion energy distribution function (IEDF) via in-situ mass spectrometer analysis indicates that in addition to a continuous flux of C neutrals the growing film is exposed to an ion flux ϕi consisting of approximately 95% of Ar⁺ ions and about few percent of C⁺ ions.

This incident flux deposited at low temperature (Ts<150° C.) generates a-C films with a suitable combination of high hardness (H=30-40 GPa), low friction (CoF=0.1−0.2) in dry condition against steel, ultra-smooth surface, an electrical resistivity as low as ˜10-4 Q·cm⁻¹ and a film density of 2.6-2.8 g·cm-3. The sp3 fraction was estimated to be approximately 50-60%. The growth of highly dense a-C films by HiPIMS to large extent depends on the mass and energy of the incident ion species and very importantly on the flux ratio of bombarding ion species to depositing atoms.

According to the findings by J. Schwan et al “Tetrahedral amorphous carbon films prepared by magnetron sputtering and dc ion plating”, in Journal Applied physics 79 (1996) 1416, producing ta-C coatings with sp3 fraction of approximately 87%, simi-lar level as vacuum arc evaporation, requires a process condition capable of offering a very high incident ion/carbon flux ratio ϕi/ϕn of 10 or more during the carbon film growth. However, it is known that the ion-to-neutral flux ratio ϕi/ϕn for HiPIMS discharge is typically in the range between 2 to 6.

One strategy to increase the ion-to-neutral flux can consist in the increase of the peak power density of the HiPIMS pulses while keeping all the other process parameters constant. This way, the plasma density is enhanced which tends to improve the degree of ionization of the plasma and ultimately increase the contribution of ions over neutrals during the film growth. Interesting improvement of the mechanical properties of the a-C coatings was observed while increasing the peak power density.

Unfortunately, increasing the peak power during the HiPIMS pulses has the dramatic effect to increase the frequency of arcing at the surface of the graphite target, as demonstrated in FIG. 1. These arcing events are partially responsible of the emission of large macroparticles which results in the collection of undesirable surface defects (see FIG. 2) leading to high coating roughness and possibly lower coating performance during applications. In order to obtain an optimum surface quality a lower peak power is needed, below 0.5 kW·cm⁻². However, reducing the peak power during the HiPIMS pulses will dramatically decreases the ion bombardment during the a-C film growth and thus produce less wear-resistant coatings. It is therefore crucial to apply an alternative ion source to densify the carbon coatings.

In their experiments, the inventors on the other hand have surprisingly noticed that when simultaneously operating a HiPIMS source at relatively low peak power density (0.5 kW·cm⁻²) with an adjacent auxiliary plasma source during the a-C film growth the mechanical properties of the a-C films are dramatically improved to a level close to vacuum arc evaporation methods while keeping the surface quality at a very high level, similar to sputtering methods.

The inventors have discovered that it is surprisingly possible to produce in an industrial coater system a wear-resistant coatings of superhard material made of amorphous carbon with, at the same time, a very high surface quality by operating simultaneously a HiPIMS source at relatively low peak power density (0.5 kW·cm⁻²) with an adjacent auxiliary plasma source, in which the process pa-rameters of both plasma sources are properly adjusted in such a way of increasing the density of the sputtered a-C layer through an intense but periodic ion bombardment treatment leading to coating properties close to high sp3 fraction ta-C films even at low temperature (the term low temperature is used in the context of the present invention for referring to temperature at the surface of the substrate of at most 150° C. and preferably below 150° C.).

As discussed above, sputtering methods can be classified in terms of duty cycle (the percentage of the time the pulse is on) and the peak power density supplied at the target racetrack. For the purpose of the present invention, we define the term conventional magnetron sputtering method, a process operating in which the power density of individual pulses is typically below 80 W·cm⁻² and the pulse frequency is in the range of 0 to 250 KHz. In HIPIMS method, the power density of individual pulses is more than 0.50 KW·cm⁻² with a duty cycle in the range of 0.5% to 10%. All discharge operations above the conventional magnetron sputtering power density limit and below the HiPIMS range are referred to as intermediate power impulse magnetron sputtering method called InPIMS. The InPIMS methods are operating in the intermediate power density 0.08-0.50 KW·cm⁻² with a duty cycle above 10%. These definitions will be used throughout this description.

To keep the coating system at low temperature coating processes suitable to reach optimum sp3 bond fraction according to the present invention, the vacuum coating chamber was equipped with special protective shields which allow increasing heat dissipation in such a manner that high efficient low temperature coating process can be conducted without compromising the deposition rate, for example. The corresponding coating device is more closely described in WO2019025559. The vacuum coating chamber has no radiation heaters. However, the vacuum coating chamber can also comprise one or more radiation heaters, which can be used as heat sources for introducing heat within the chamber in order to heat the substrates to be coated.

According to the present invention, the hard carbon layer may comprise at least one superhard hydrogen-free amorphous carbon layer by means of hybrid InPIMS/auxiliary plasma source method, wherein, to deposit the superhard carbon layer, at least one target comprising C, for example a graphite target, is used as the source of primary ions (Ar⁺ and C⁺ to some extent) as well as carbon neutrals, said target being used for sputtering in the coating chamber and operated with InPIMS power supply with the inert atmosphere having at least one inert gas, preferably argon, and at least one auxiliary plasma source, for example, a plasma ARC conventionally used for precleaning the substrate prior coating deposition (see e.g WO2014090389A1), is used as the source of additional ion bombardment, see FIG. 3. The term “superhard” in this context means any coating with a hardness above 40 GPa.

The electrical InPIMS power supplied to the graphite target is preferentially delivered in pulses with lengths (tpulse) of less than 10 ms, preferably less than 1 ms, particularly preferably less than 0.1 ms, with peak power density and duty cycle preferably in the range of intermediate pulsed methods for achieving a sufficient highly ionized Ar plasma during the InPIMS pulses suitable to promote the growth of dense and hard a-C but not energetic enough to induce arcing events at the surface of the graphite target, see FIG. 1, resulting in the deposition of a smooth a-C layer with less surface droplets.

The inventors found surprisingly that it is preferable for producing the inventive superhard a-C layer to attain growth conditions with a high ion-to-neutral flux ratio ϕi/ϕn. According to one embodiment of the present invention, this condition is attained by applying simultaneously a InPIMS plasma source at low peak power and a Plasma ARC. Here, the substrate rotation results in deposition from each graphite target to a thickness of a few nanometer before the film is exposed to the intense Ar⁺ ion flux from the adjacent auxiliary plasma source. Ar ions are bombarding and/or implanted into the a-C layer when exposed to the adjacent auxiliary plasma source and provide densification to achieve high sp3 a-C film during the time substrate is facing auxiliary plasma source.

While the inventors do not wish to be held to any particular theory, it is believed that the periodic ion treatment by the Ar⁺ ions from the auxiliary plasma source is very effective in further densifying the growing a-C film by InPIMS due to the fact that the zone of intense near-surface intermixing is much broader compared to the a-C layer thickness deposited between successive exposition to the InPIMS source. Thus, under such conditions the Ar⁺ ions penetrate deep into the near-surface region inducing the transformation of the surrounding carbons from sp2 to sp3 leading to coating properties closer to high sp3 fraction ta-C films conventionally observed with vacuum arc deposition method.

The inventors have surprisingly found that to deposit the above-mentioned superhard a-C coating, a proper adjustment of the rotation speed of the carousel with substrates to be coated and applied power to the target has to be done in such a way that the thickness of the a-C layer deposited per pass in front of a graphite target is equal or lower to than the penetration depth of Ar+ ions in a-C. Proper adjustment of the deposition rate vs rotation speed needs to be carried out ahead of deposition.

The process may be carried out for example at an Ar pressure of about 0.3 to 0.5 Pa.

The negative bias voltage can be continuous, or synchronized with the InPIMS pulses applied to the graphite targets or the auxiliary plasma source, wherein the bias voltage value is between −50 V and −150 V, more preferably between −50 V and −100 V, so that the kinetic energy of the incident ions is suitable to promote sp2 to sp3 transformation.

The arc current produced by the Plasma ARC is preferentially continuous or pulsed with an averaged current value preferably higher than 10 A, most preferably higher than 30 A, further preferably higher than 50 A.

During the deposition process, the temperature of the substrate may be kept at less than 150° C., most preferably less than 120° C., and further preferred even at less than 100° C., so that carbon graphitization during the film growth is avoided. The process may be conducted without external heating.

The hardness of the hydrogen-free amorphous is preferably higher than 40 GPa. The preferred range for the hardness of the amorphous carbon layer is between 20 GPa and 60 GPa.

The elastic modulus of the hydrogen-free amorphous layer is preferably higher than 300 GPa. The preferred range for the elastic modulus of the amorphous carbon layer is between 200 and 450 GPa.

The fraction of the sp3 bonds in the hydrogen-free amorphous carbon is preferably higher than 50% further preferably higher than 70% for example between 50% and 85%.

Preferably, the said at least one hydrogen-free amorphous carbon exhibits a very smooth surface characterized by R_{z}<0.5 μm.

Preferably, the argon concentration in the said at least one hydrogen-free amorphous carbon layer is preferably lower than 10 at. %, as for example 5 at. %.

Preferably, the electrical resistivity of the said at least hydrogen-free amorphous carbon layer is lower than 10-3 Ωcm⁻¹, preferably lower than 10-4 Ω·cm⁻¹.

Preferably, the hydrogen-free amorphous carbon layer has an anthracite gray value L* between 50 and 55 (according to the CIE 1976 L* a* b* color space based on a D65 standard illumination)

Preferably, the abrasive wear rate (in ball crater micro abrasion test according to DIN EN ISO 1071-6) of the said at least hydrogen-free amorphous carbon layer is lower than 2.0.10-16 m3/Nm.

Preferably, the total thickness in the said at least one hydrogen-free amorphous carbon layer is higher than 0.1 μm, preferably higher than 0.5 μm, most preferably higher than 1.0 μm. For specific applications such as for example fuel cell bipolar plates, it might make sense to choose a thickness between 0.01 μm and 0.1 μm, including the limits of this range.

Although described above for the argon ion bombardment and/or implantation, embodiments of the present invention may also be applied for implanting other elements having larger mass than carbon including noble-gas elements such as (Ne, Ar, Kr, Xe.

Although described above for the auxiliary plasma source Plasma ARC conventionally used for pre-cleaning the substrate prior coating deposition, embodiments of the present invention may also include ion sources such as HiPIMS source, vacuum cathodic arc, ion beam, and other sources known in the art.

It is of special advantage to produce carbon coatings with the inventive method as described. However it is the inventors' understanding that the present invention can also be used to produce other high-quality superhard coatings such as for example nitride-based (e.g. AITiN, AlCrN, TiN, SIN, BN), and/or carbide-based (e.g. SiC, HfC, WC, MoC, BC) and oxide-based coatings (e.g. Al2O3, Y2O3, AlCrO, Cr2O3, AlTiO). Oxynitrides and multicomponent materials (also referred to as high entropy alloy) may as well take advantage of this new method.

The invention will now be explained in detail and by way of example with reference to a process description and figures.

### BRIEF DESCRIPTION OF THE FIGURES

FIG. 1: Impact of the peak power density supplied to the racetrack area during each HiPIMS pulses on the arcing rate at the surface of the target.

FIG. 2: Impact of the peak power density supplied to the racetrack area during each HiPIMS pulses on surface quality of the as-deposited a-C coatings.

FIG. 3: Comparison of the coating hardness of carbon coatings deposited with and without the inventive method at different position along the height of the coating chamber (on substrate carousel).

FIG. 4: Cross-section SEM micrograph of the inventive hydrogen-free superhard a-C carbon coating

FIG. 5: Optimization of the process conditions: (a) Projected ion range versus ion kinetic energy. and b) impact of the rotation speed onto thickness of the a-C layer deposited per pass.

FIG. 6.: Abrasive wear rate of few selected carbon based coatings based on the ball crater micro abrasion test (according to DIN EN ISO 1071-6).

FIG. 7: Plan-view light optical micrograph of selected hydrogen-free carbon coatings: (a) a-C(38 GPa), (b) Inventive superhard a-C coating (52 GPa), and (c) Cathodic Arc ta-C(60 GPa).

FIG. 8: Surface profilometer profile of few selected hydrogen-free carbon coatings: (a) Inventive superhard a-C coating (52 GPa) and (b) Cathodic Arc ta-C(60 GPa)

FIG. 9: Friction coefficient vs sliding distance of few selected carbon-based coatings: (a) Inventive superhard a-C coating (52 GPa) and (b) Cathodic Arc ta-C(60 GPa)

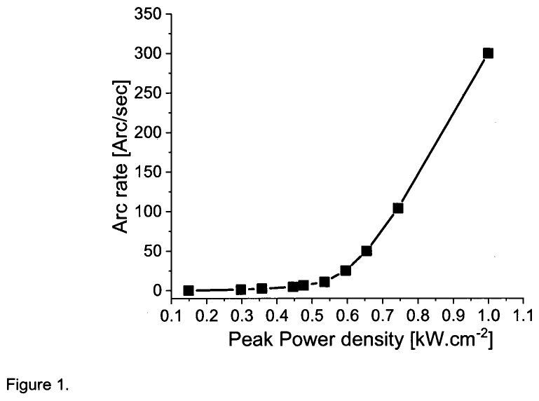

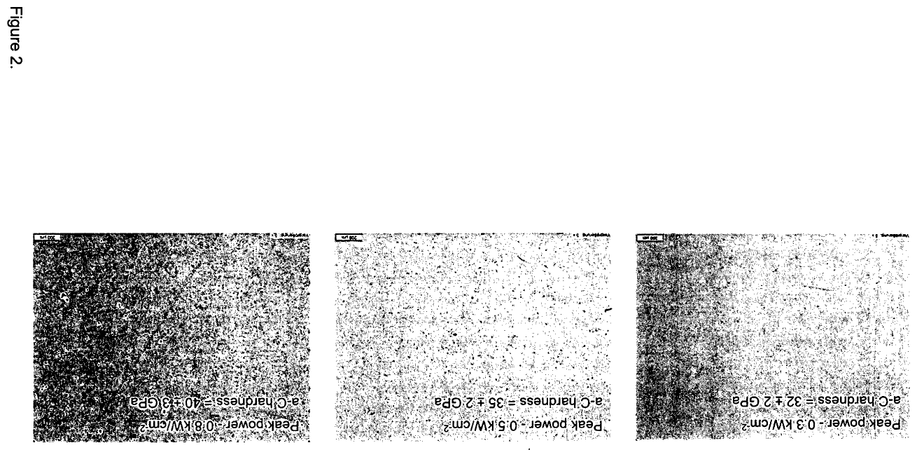

### EXAMPLE 1

In order to produce the carbon coating system according to the present invention the workpieces made of steel with hardness of 62 HRC were placed in an Oerlikon Balzers INGENIA s3p vacuum processing chamber equipped with three targets of chromium and three targets of graphite, whereupon the vacuum chamber was pumped down to a pressure of about 10⁻⁵ mbar.

In order to demonstrate the effectiveness of the periodic ion densification treatment during the growth of a-C according to the present invention, two samples one with and one without the periodic ion densification treatment were deposited with identical parameters for all remaining process steps, including the deposition of the metallic adhesion-promoting layer and the metal carbide transition layer.

As a first part of the process, a plasma heating process was carried out for 30 minutes in order to bring the substrates to be coated to a higher temperature of approximately 170° C. and to remove volatiles substances from the surface of the substrate and the vacuum chamber walls being sucked out by the vacuum pump. In this pretreatment step, an Ar hydrogen plasma is ignited by means of a Plasma ARC between an ionization chamber and an auxiliary anode.

An Ar ion plasma etching process, of 20 minutes duration, is initiated by activating the low voltage arc ionization method.

The Ar ions are drawn from the Plasma ARC by means of a negative bias voltage of 120 V onto the substrates to be cleaned with the primarily goal to remove impurities such as native oxides or also organic impurities via ballistic removal (i.e. native oxides and impurities are sputtered etch by the intense Ar+ ion bombardment) to insure a good layer adhesion of the adhesive metal layer that takes place after the ion cleaning.

As the next process step, a 300 nm-thick adhesion-promoting Cr layer is de-posited by means of HIPIMS method according to the present invention directly onto the surface of the substrate to be coated using the following process parameters: a power density of individual pulses of 700 W·cm⁻², an Ar total pressure of 0.3 Pa and a constant bias voltage of −50 V at a coating temperature lower than 180° C. for 30 minutes.

Then, immediately afterwards, a 200 nm-thick graded CrC transition layer was deposited by co-sputtering method using the following process parameters: the three graphite targets were operated with an average power Pav starting from 80 W·cm⁻² to 161 W·cm⁻² in order to gradually increase the C content, wherein the chromium targets were operated with a constant average power Pav of 20 W·cm⁻². The power density and duty cycle of the individual pulses supplied to the graphite targets were within the intermediate pulsed method range in accordance with the present invention. Regarding the chromium targets, the power density of the individual pulses was selected at 600 W·cm⁻² to provide suitable metal-ion irradiation during the film growth.

Finally, a 0.7 μm-thick wear-resistant hydrogen-free a-C layer was deposited in accordance with the present invention wherein the three graphite targets were operated with an average power PAv of 60 W·cm⁻² and a power density of individual pulses of 0.3 kW·cm⁻², with a tpulse of 0.05 ms, at a total pressure of 0.3 Pa and a constant bias voltage of-100 V at a coating temperature of 120° C. for a total deposition duration of 196 minutes. The associated sample deposited under only InPIMS plasma source is listed as “InPIMS a-C”

A second a-C layer was deposited with the hybrid InPIMS/Plasma ARC method in accordance with the present invention where this time in addition to the InPIMS graphite source an adjacent Plasma ARC was applied simultaneously with the following parameters: a continuous ion source voltage of 50 V with a continuous Arc cur-rent of 30 A. The associated sample deposited under the hybrid InPIMS/Plasma ARC method is labelled as “Inventive superhard a-C”.

Surprisingly, the current measured at the substrate location during the deposition of the a-C layer under the hybrid InPIMS/Plasma ARC method was almost 4 times higher than during the deposition of the a-C with only InPIMS source. By neglecting the contribution of electron in the total current measured at the substrate, a higher current corresponds to a process condition with a more intense ion bombardment occurring during the a-C film growth for the hybrid method. Furthermore, since the deposition rate and hence the incident carbon neutral flux is similar during both the growth of “conventional InPIMS a-C” and “Inventive superhard a-C”, it is clear that a higher incident ion/carbon flux ratio is achieved during the growth of the “Inventive superhard a-C”.

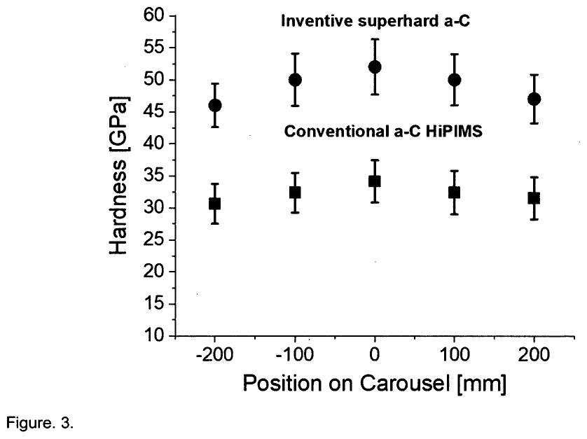

Evaluation of the coating hardness (HIT) along the height of the coating chamber was carried out for both a-C samples using a load of 10 mN on a Fischerscope Instruments nano indenter. The results are shown in the FIG. 3. Conventional hydrogen-free a-C deposited at intermediate HiPIMS peak pulse power of 0.3 kW·cm⁻² under the present conditions exhibited an average coating hardness of 32±2 GPa with an excellent distribution of the film mechanical properties along the coating chamber height. Surprising-ly, the average coating hardness (HIT) of the inventive superhard a-C coating was much higher in the range of 48±2 GPa confirming the enhanced densification of the a-C during the film growth.

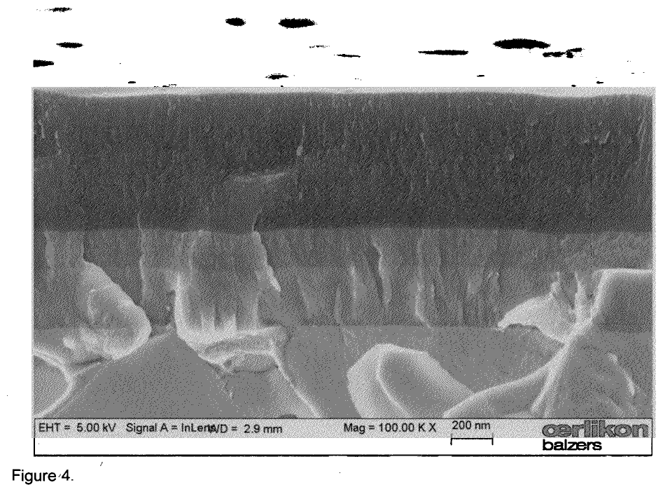

Cross-section scanning electron microscope image of the inventive superhard a-C coating, shown in FIG. 4, confirms the very dense and compact microstructure of the inventive hard carbon coating.

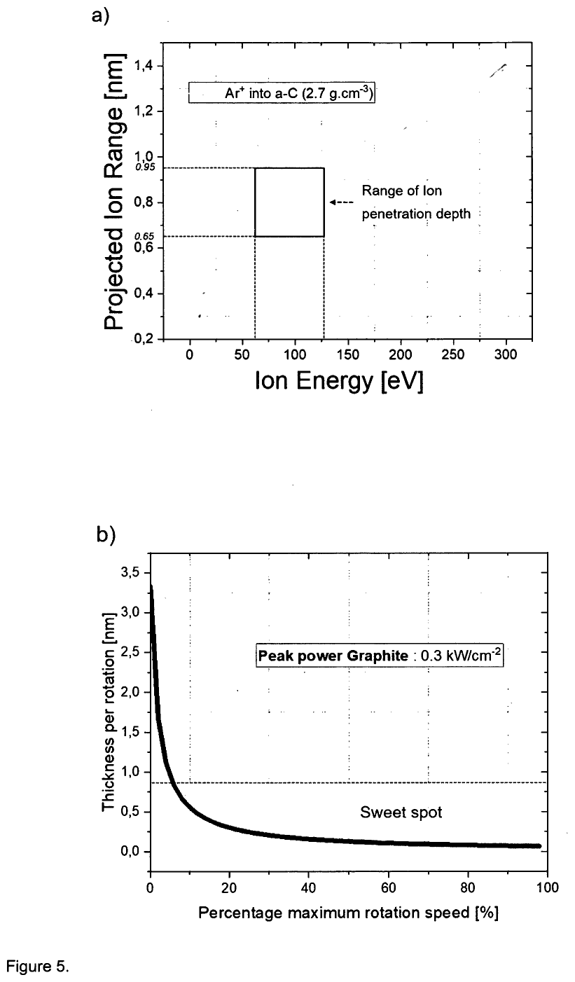

While the inventors do not wish to be held to any particular theory, it is believed that the periodic irradiation by supplement Ar ions from the auxiliary plasma source was very effective in densifying the growing film due to the fact that the zone of intense near-surface intermixing of ˜0.7-0.8 nm, determined by the collision-cascade range of the 100 eV Art ions (see FIG. 5. (a)), was much larger than the a-C layer thickness deposited between successive exposition to the graphite target. For example, as shown in FIG. 5. (b), considering a maximum rotation speed of 100% of the substrate holder as used to deposit the a-C film, the thickness of the a-C layer deposited per pass under a graphite target supplied by a peak power 0.3 kW·cm⁻² was ˜0.1 nm based on deposition rate calibrations. Thus, under such conditions the Ar⁺ ions penetrate deep into the near-surface region and create a large number of recoils to ensure enhanced film densification and possibly the transformation of the surrounding carbons from sp2 to sp3 into subsurface positions.

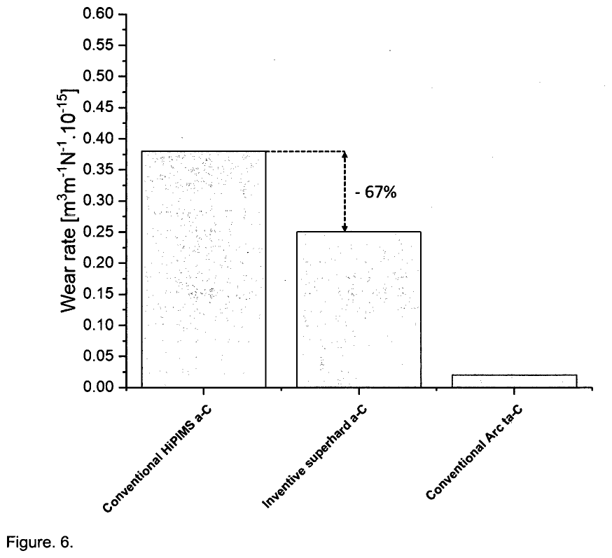

In order to further confirm the improvement of the mechanical properties of the inventive superhard a-C coating, a ball crater micro abrasion method was applied to evaluate the abrasive wear resistance of few selected carbon coatings, namely the InPIMS a-C″, the “inventive superhard a-C” as deposited with the hybrid InPIMS/Plasma Arc method and a 1.0 μm-thick hydrogen-free hard carbon coating of 60 GPa deposited by cathodic vacuum arc evaporation. The calculated wear coefficient for each of these 3 carbon coatings is presented in the FIG. 6. A clear trend is observed, the higher the hardness value the lowest the abrasive wear coefficient. In addition, one can observed a reduction of −67% of the wear coefficient of the inventive superhard a-C coating in comparison to the InPIMS a-C layer, again confirming the importance of the periodic but intense ion irradiation for the a-C film densification.

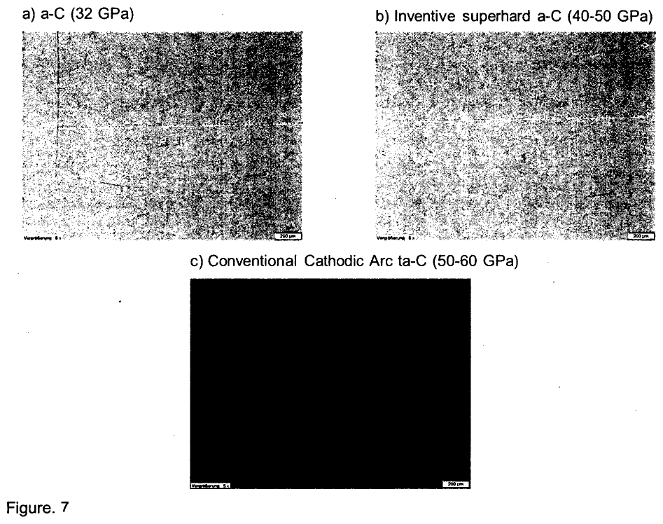

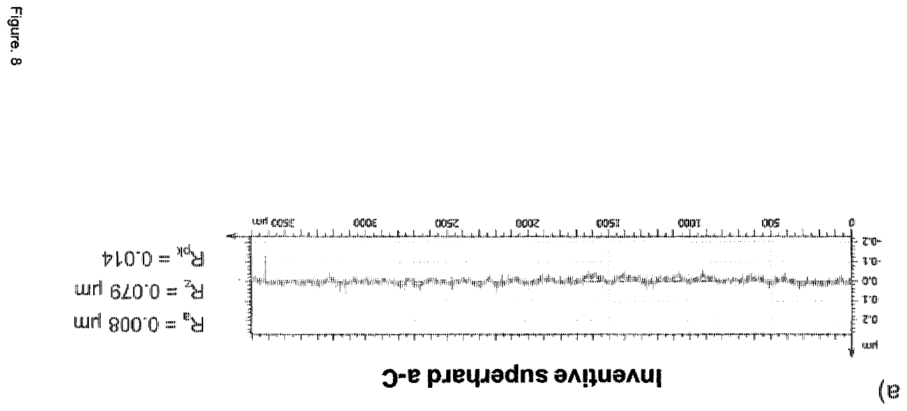

The surface quality of the inventive superhard a-C coating was also compared with the other carbon coatings presented previously. The light optical plan-view images of these three carbon coatings are presented in the FIG. 7. As observed in FIG. 7. (c), ta-C coatings deposited by cathodic arc evaporation exhibit large amount of macro-particles. Surprisingly, both a-C coatings deposited by InPIMS exhibit an excellent surface quality with virtually no sur-face defects, confirming that the source of macro-particles is coming from the arcing events occurring at the surface of the graphite target.

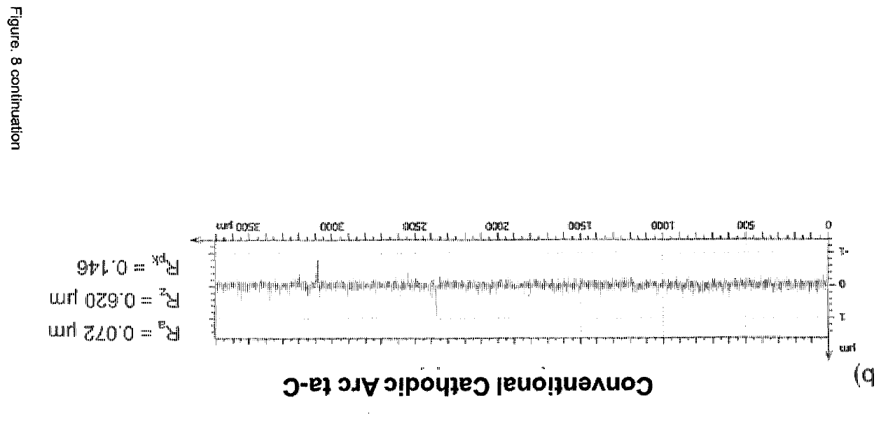

Comparison of the surface roughness of the inventive superhard a-C to ta-C by cathodic arc evaporation, as shown in FIG. 8, also confirm the very high quality in terms of smoothness (in other words, low roughness Ra and/or Rz and/or Rpk) of the a-C growth by the hybrid InPIMS/low-voltage arc method.

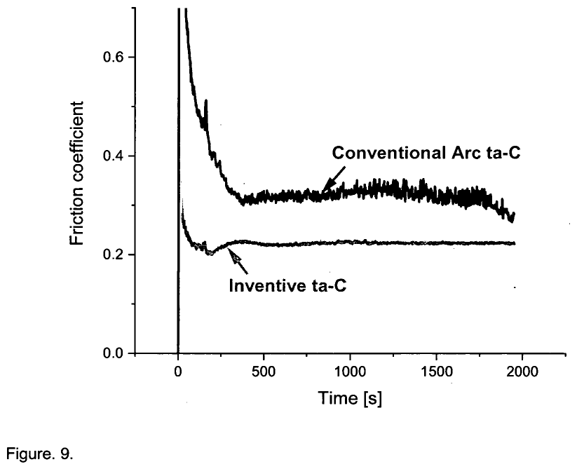

The friction of the inventive superhard a-C coating was tested using the pin-on-disk test (pin-on-disk tribometer, CSM Instruments). The test was performed in air under dry condition at a temperature of 22° C. and 43% relative hu-midity. The sample was abraded against an uncoated 100Cr6 steel ball with a diame-ter of 3 mm. The steel ball served as a static friction partner and the coated sample was turned underneath it (radius 5 mm, speed 0.3 m/s). A 30 N load was applied on the ball. This corresponds to an instantaneous contact pressure of 2.2 GPa applied onto the surface of the hard carbon layer. The measurement of the inventive coating was compared to a 1.0 μm-thick hydrogen-free hard carbon coating of 60 GPa deposited by cathodic arc evaporation method. Representative friction coefficient after 33 minutes of dry sliding for these two coatings are plotted in FIG. 9.

Surprisingly, the steady-state friction coefficient of the inventive layer is at a low level, COF˜0.2, demonstrating the very good friction behavior of the inventive hard-carbon coating. On the other hand, the friction coefficient of the arc-evaporated ta-C coating is at a higher level most probably due to the higher surface roughness emphasized by the previously mentioned surface profilometer measurements.

Very surprising was the fact that the inspection of the abraded surfaces after the test shows significantly less layer and slightly less counterpart component wear in general for the inventive layer than the much rougher arc-evaporated ta-C coating (width of the abrasion part of the coating 249 μm vs 669 μm, diameter of the abraded area of the ball 270 μm vs 984 μm for the inventive layer and arc-evaporated ta-C, respectively), demonstrating a suitable combination of en-hanced wear-resistant properties, low friction and improved surface quality of the in-ventive hard carbon coating compared to the state of the art superhard carbon coat-ing. One possible explanation for this surprising lower abrasion wear on the uncoated counter-body ball could be due to the smoothness and low-defect density provided by this inventive superhard a-C layer deposited by the hybrid InPIMS/Plasma ARC method.

A method for forming a coatings on a substrates was disclosed, the process comprising the steps of:
mounting the substrate on carrier means within a vacuum chamber;
providing coating means comprising at least a first device in the form of a deposition device positioned adjacent the carrier means and adapted for depositing a selected material onto the substrates and
providing a second device adapted for providing positive non-reactive ions and
operating the coating means for forming a selected coating on the substrates while periodically moving at least one of the carrier means and the coating means relative to each other along a path selected to provide substantially equal deposition rates for similarly configured spaced substrates. A negative bias is applied to the substrates for effecting a bombardment of the selected material deposited on the substrates thereby increasing the density of the material deposited.

The coating means can be means for performing physical vapor deposition (PVD) and operating the coating means is performing physical vapor deposition.

The PVD means can comprise magnetron sputter means and operating the coating means is performing magnetron sputtering.

The magnetron sputtering can be performed in a pulsed manner and the maximum power density in a pulse is at least 0.08 kW·cm⁻²

Preferably the maximum power density is chosen to be at most at 0.5 kW·cm⁻².

The duty cycle of at least some, preferably the average duty cycle of the pulses, most preferably the duty cycle of all pulses can be chosen to be above 10%.

The method can comprise the step of pre-cleaning the substrates prior coating deposition where second device providing positive ions is used to perform such precleaning and preferably the second device comprises a plasma source.

The ions provided by the second device are ions preferably having a larger mass than carbon.

The ions preferably comprise Argon ions and/or elements selected from members of the group formed by noble-gas elements such as (Ne, Ar, Kr, Xe) and/or mixtures thereof.

What is claimed is:

1. A method for forming a coating on a substrate comprising the steps of:
mounting the substrate on carrier means within a vacuum chamber;
providing coating means comprising at least a first device in the form of a deposition device positioned adjacent the carrier means and adapted for depositing a selected material onto the substrates and
providing a second device adapted for providing positive non-reactive ions and
operating the coating means for forming a selected coating on the substrates while periodically moving at least one of the carrier means and the coating means relative to each other along a path selected to provide substantially equal deposition rates for similarly configured spaced substrates, wherein a negative bias is applied to the substrates for effecting an ion bombardment on the selected material deposited on the substrates thereby increasing the density of the material deposited.

2. The method according to claim 1, wherein the coating means are means for performing physical vapor deposition means (PVD) and operating the coating means is performing physical vapor deposition.

3. The method according to claim 2, wherein the PVD means comprise magnetron sputter means and operating the coating means is performing magnetron sputtering.

4. The method according to claim 3, wherein magnetron sputtering is performed in a pulsed manner and the maximum power density in a pulse is at least 0.08 kW·cm⁻²

5. The method according to claim 4, wherein the maximum power density is at most at 0.5 kW·cm⁻².

6. The method according to claim 5, wherein the duty cycle of at least some, preferably the average duty cycle of the pulses, most preferably the duty cycle of all pulses can be chosen to be above 10%.

7. The method according to claim 1, wherein the method comprises the step of pre-cleaning the substrates prior coating deposition where second device providing positive ions is used to perform such precleaning and preferably the second device comprises a plasma source.

8. The method according to claim 1, wherein the ions provided by the second device are ions having larger mass than carbon.

9. The method according to claim 8, wherein the ions comprise Argon ions and/or elements selected from members of the group formed by noble-gas elements such as (Ne, Ar, Kr, Xe) and/or mixtures thereof.
